(19) United States
(12) Patent Application Publication
(10) Pub. No.: US 2022/0284336 A1
(43) Pub. Date: Sep. 8, 2022

(54) PROCESSING METHOD FOR QUANTUM CIRCUIT, ELECTRONIC DEVICE, AND STORAGE MEDIUM

(71) Applicant: Beijing Baidu Netcom Science Technology Co., Ltd., Beijing (CN)

(72) Inventors: Shusen Liu, Beijing (CN); Runyao Duan, Beijing (CN); Danxiang Wu, Beijing (CN); Shenjin Lv, Beijing (CN)

(73) Assignee: Beijing Baidu Netcom Science Technology Co., Ltd., Beijing (CN)

(21) Appl. No.: 17/752,036

(22) Filed: May 24, 2022

(30) Foreign Application Priority Data
Jul. 14, 2021 (CN) 202110796240.7

(51) Int. Cl. G06N 10/20; G06N 10/40

(52) U.S. Cl. CPC G06N 10/20; G06N 10/40

(57) ABSTRACT

A processing method for a quantum circuit, an electronic device, and a storage medium are provided, and relates to the field of quantum computing, and in particular to the field of quantum circuit compilation. The method includes: acquiring a first measurement order of respective logical qubits in the quantum circuit; determining a physical qubit order corresponding to the first measurement order based on a target mapping relationship between the respective logical qubits and respective physical qubits in a chip coupling diagram, wherein the target mapping relationship is obtained by updating based on an initial mapping relationship between the respective logical qubits and the respective physical qubits; determining a second measurement order of the respective logical qubits of the quantum circuit based on the physical qubit order and the initial mapping relationship; and measuring the quantum circuit based on the second measurement order, to obtain a measurement result.

### CROSS-REFERENCE TO RELATED APPLICATION

This application claims priority to Chinese patent application No. 202110796240.7, filed on Jul. 14, 2021, which is hereby incorporated by reference in its entirety.

### TECHNICAL FIELD

The present disclosure relates to the field of quantum computing, and in particular to the field of quantum circuit measurement.

### BACKGROUND

A Noisy Intermediate-Scale Quantum (NISQ) device, which is constrained by the chip topology logic, restricts the quantum gate operation acting on two qubits to be applied only on some specially selected adjacent qubit pairs. In order to enable the algorithm described by the quantum circuit to operate on the quantum device, it is necessary to convert and optimize the quantum circuit, such that the number of basic quantum gates of the quantum circuit is as small as possible while the quantum circuit meets the limitation of the physical device.

### SUMMARY

The present disclosure provides a processing method and apparatus for a quantum circuit, an electronic device, and a storage medium.

According to an aspect of the present disclosure, there is provided a processing method for a quantum circuit including:

acquiring a first measurement order of respective logical qubits in the quantum circuit;

determining a physical qubit order corresponding to the first measurement order based on a target mapping relationship between the respective logical qubits and respective physical qubits in a chip coupling diagram, wherein the target mapping relationship is obtained by updating based on an initial mapping relationship between the respective logical qubits and the respective physical qubits;

determining a second measurement order of the respective logical qubits of the quantum circuit based on the physical qubit order and the initial mapping relationship; and

measuring the quantum circuit based on the second measurement order, to obtain a measurement result.

According to another aspect of the present disclosure, there is provided an electronic device including:

at least one processor; and

a memory connected communicatively to the at least one processor, wherein

the memory stores instructions executable by the at least one processor, and the instructions, when executed by the at least one processor, enable the at least one processor to perform the method in any one embodiment of the present disclosure.

According to another aspect of the present disclosure, there is provided a non-transitory computer readable storage medium storing computer instructions, wherein the computer instructions, when executed by a computer, cause the computer to perform the method in any one embodiment of the present disclosure.

It should be understood that the contents described in this section are not intended to recognize key or important features of embodiments of the present disclosure, nor are they intended to limit the scope of the present disclosure. Other features of the present disclosure will become easily understood from the following description.

### BRIEF DESCRIPTION OF THE DRAWINGS

The drawings are used to better understand the solution and do not constitute a limitation to the present disclosure. In the drawings:

FIG. 1 is a schematic diagram of a quantum circuit before conversion according to an embodiment of the present disclosure;

FIG. 2 is a schematic diagram of a quantum circuit after conversion according to an embodiment of the present disclosure;

FIG. 3 is a schematic diagram of a processing method for a quantum circuit provided by an embodiment of the present disclosure;

FIG. 4 is a schematic diagram of a chip coupling diagram of an embodiment of the present disclosure;

FIG. 5 is a first schematic diagram of a processing method for a quantum circuit provided by another embodiment of the present disclosure;

FIG. 6 is a second schematic diagram of a processing method for a quantum circuit provided by another embodiment of the present disclosure;

FIG. 7 is a schematic diagram of a logic circuit in a still embodiment of the present disclosure;

FIG. 8 is a schematic diagram of a chip coupling diagram in a still embodiment of the present disclosure;

FIG. 9 is a schematic diagram of a physical circuit in a still embodiment of the present disclosure;

FIG. 10 is a schematic diagram of a processing apparatus for a quantum circuit provided by an embodiment of the present disclosure;

FIG. 11 is a schematic diagram of a processing apparatus for a quantum circuit provided by another embodiment of the present disclosure; and

FIG. 12 is a block diagram of an electronic device for implementing an processing method for a quantum circuit of an embodiment of the present disclosure.

### DETAILED DESCRIPTION

The exemplary embodiments of the present disclosure will be described below in combination with drawings, including various details of the embodiments of the present disclosure to facilitate understanding, which should be considered as exemplary only. Therefore, those of ordinary skill in the art should realize that various changes and modifications can be made to the embodiments described herein without departing from the scope and spirit of the present disclosure. Likewise, descriptions of well-known functions and structures are omitted in the following description for clarity and conciseness.

In order to facilitate the understanding of the technical solution of the embodiment of the present disclosure, the relevant technologies of the embodiment of the present disclosure are described below. The following relevant technologies, as an optional solution, can be arbitrarily combined with the technical solution of the embodiment of the present disclosure, which belong to the protection scope of the embodiment of the present disclosure.

In the embodiment of the present disclosure, a quantum circuit refers to a circuit for acting on qubits and describing certain specific algorithms. Without considering the physical constraints, the quantum circuit can be called as a logic circuit (LC), wherein each of qubits is called as a logical qubit and is denoted as Qᵢ, i∈{0, 1, 2, . . . , n}, and n indicates the number of logical qubits in the logic circuit. The qubits on the physical device are called as physical qubits and are denoted as Qᵢ, i∈{0, 1, 2, . . . , m}, and m indicates the number of physical qubits, m n. In the practical application, it is necessary to establish the mapping between qubits in the quantum circuit and qubits in the physical device, to operate the quantum circuit in the physical device. However, due to the connectivity constraints of chip coupling in the physical device, a part of the quantum circuit cannot operate directly in the physical device. In order to make the algorithm described by the quantum circuit operate on the quantum device, it is necessary to convert and optimize the quantum circuit and update the qubit mapping accordingly. The quantum circuit obtained after conversion and meeting the physical constraints can be called as a physical circuit (PC), which can be executed on the physical device.

In the relevant technologies, the quantum circuit is layered, and then the mapping is found and updated for each layer. The layer is a set of some of quantum gates (hereinafter referred to as “gates”) in the quantum circuit. There can be multiple layers in a quantum circuit, and there is an order between these layers. The layers do not intersect with each other. The union of all layers is a set of all gates in a quantum circuit. The layers are constructed as follows:

all gates in the quantum circuit move towards the input terminal as far as possible, wherein in the process of moving, gates sharing a qubit cannot cross each other;

and

gates acting on the same qubit are divided into different layers from left (input) to right (output).

In the conversion of the quantum circuit, it is needed to correspond the logical qubits to the physical qubits one-to-one. This correspondence relationship will be transformed or updated with the introduction of the swap gate inserted in the quantum circuit in the conversion process. This correspondence relationship can also be called as the mapping relationship, which is denoted as τ. In a case that q₁ and q₂ are different logical qubits, for a certain mapping relationship τ, τ(q₁)≠τ(q₂) should be satisfied.

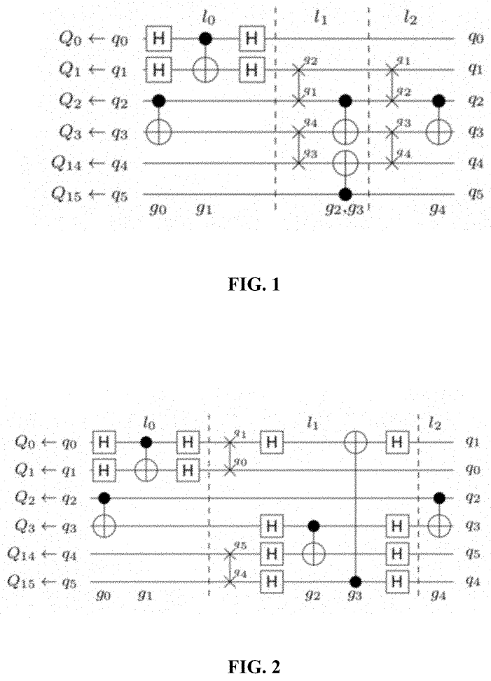

In a more advanced integrated algorithm, the quantum circuit is first layered based on a depth, and then the A * (A star) search algorithm is used to find and update the mapping for each layer, and the quantum circuit is converted and optimized accordingly. The optimization skill thereof adopts the forward-looking strategy. The output circuit obtained by this algorithm has fewer quantum gates and a smaller circuit depth. FIG. 1 shows a schematic diagram of an exemplary quantum circuit before optimization, which includes a plurality of quantum gates g₀, g₁, g₂, g₃, and g₄ acting on qubit pairs, distributed in three layers l₀, l₁, and l₂ respectively. After updating the mapping using the A * search algorithm, the schematic diagram of the optimized quantum circuit as shown in FIG. 2 is obtained. It can be seen that, for the circuit with more quantum gates, the number of gates will be greatly reduced in the circuit, but the defect is that the operation time of circuit conversion is greatly prolonged.

Exemplarily, the way to determine the qubit mapping further includes:

(1) The quantum circuit conversion problem is converted and solved by using the optimization problem solving tool.

(2) It is determined based on a heuristic search algorithm. Similar to the A * search algorithm, a multi-layer heuristic function is designed, and different weights are defined for quantum gates in different layers of the input circuit.

In the above relevant technologies, it is necessary to find the initial mapping from the logical qubits to the physical qubits, as the input, and then search and update the mapping. Different initial mapping selections will also affect the subsequent solution results. The determination manners of the initial mapping include determination based on a greedy algorithm, determination based on the idea of the fastest subgraph isomorphism, determination based on simulated annealing, etc. These initial mapping manners generally lack the ability of global optimization.

At present, there is no feasible solution to measure the physical circuit output by the above mapping solution to obtain the measurement results based on a specific qubit order.

The processing method for the quantum circuit provided by the embodiment of the present disclosure can be used to solve at least one of the above problems.

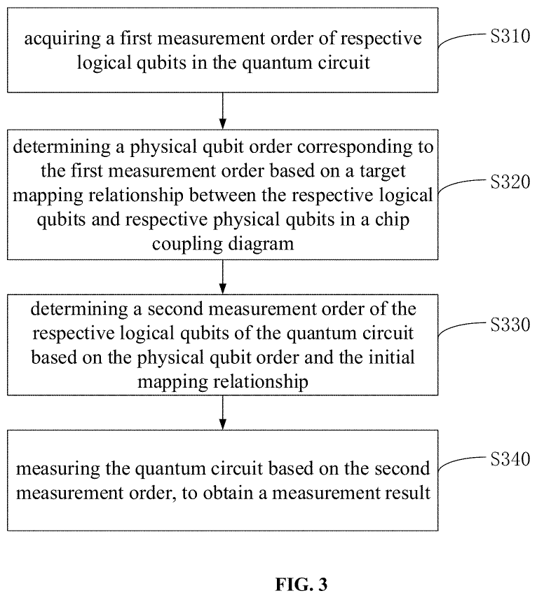

FIG. 3 shows a processing method for a quantum circuit provided by an embodiment of the present disclosure. As shown in FIG. 3, the method includes:

S310, acquiring a first measurement order of respective logical qubits in the quantum circuit;

S320, determining a physical qubit order corresponding to the first measurement order based on a target mapping relationship between the respective logical qubits and respective physical qubits in a chip coupling diagram, wherein the target mapping relationship is obtained by updating based on an initial mapping relationship between the respective logical qubits and the respective physical qubits;

S330, determining a second measurement order of the respective logical qubits of the quantum circuit based on the physical qubit order and the initial mapping relationship; and

S340, measuring the quantum circuit based on the second measurement order, to obtain a measurement result.

Exemplarily, before performing the above operations, the quantum circuit has been circuit-converted based on the initial mapping relationship between the respective logical qubits in the quantum circuit and the respective physical qubits in the chip coupling diagram, while the corresponding mapping update has been performed to obtain the target mapping relationship. It should be understood that the mapping relationship between the logical qubits and the physical qubits in a case of the quantum circuit before the conversion is different from the mapping relationship between the logical qubits and the physical qubits in a case of the quantum circuit after the conversion, so the circuit structure of the quantum circuit before the conversion is different from the circuit structure of the quantum circuit after the conversion. However, the quantum circuit before the conversion and the quantum circuit after the conversion are equivalent circuits, and are used to describe the same algorithm.

Exemplarily, the chip coupling diagram can refer to a chip architecture coupling diagram in a physical device, such as a quantum computer, and the chip coupling diagram is used to represent the coupling relationship or connectivity relationship between respective physical qubits on the chip. In some application scenarios, the quantum gate acting on an adjacent physical qubit pair in the chip coupling diagram can be performed, and the quantum gate acting on a non-adjacent physical qubit pair in the chip coupling diagram cannot be performed. Based on the target mapping relationship between the respective logical qubits and the respective physical qubits in the chip coupling diagram, the quantum circuit can be performed on the physical device corresponding to the chip coupling diagram.

Exemplarily, the first measurement order may include a preset default order or a measurement order specified by a user. Specifically, in the case where logical qubits q₀, q₁, q₂, and q₃ are included in the quantum circuit, the first measurement order can be q₁, q₂, q₃, q₀, or q₀, q₁, q₃, q₂, etc. Based on the target mapping relationship, a physical qubit Qⱼ corresponding to each logical qubit qᵢ in the first measurement order can be obtained. Therefore, a physical qubit order can be obtained, for example, Q₁, Q₀, Q₃, and Q₂. Based on the initial mapping, the logical qubits corresponding to the respective physical qubits in the physical qubit order can be obtained, so as to obtain another order of logical qubits, which is denoted as the second measurement order. The quantum circuit is measured based on the second measurement order, and the obtained measurement result is the measurement result corresponding to the first measurement order.

It can be seen that since the initial mapping relationship and the target mapping relationship, which is obtained by updating, clearly describe the mapping relationships between the logical qubits in the quantum circuit and the physical qubits in the chip coupling diagram before and after the mapping update, the final state measurement of the quantum circuit after the qubit mapping is realized based on the initial mapping relationship and the target mapping relationship. Moreover, the measurement results can be output based on the obtained first measurement order, which can meet the needs of different quantum programs for the specific qubit measurement and increase the availability of the quantum circuit.

Exemplarily, the above operation of determining the second measurement order of the respective logical qubits of the quantum circuit based on the physical qubit order and the initial mapping relationship, includes:

determining an inverse mapping relationship of the initial mapping relationship, wherein the inverse mapping relationship is a mapping relationship between the respective physical qubits and the respective logical qubits; and

mapping the physical qubit order based on the inverse mapping relationship, to obtain the second measurement order of the respective logical qubits.

Specifically, the initial mapping relationship can be a mapping relationship between the logical qubits and the physical qubits, and are used to determine the physical qubits corresponding to the logical qubits. The inverse mapping relationship thereof is a mapping relationship between the physical qubits and the logical qubits, and are used to determine the logical qubits corresponding to the physical qubits. By determining the inverse mapping, the corresponding second measurement order can be obtained accurately based on the physical qubit order, to ensure the accuracy of the measurement results.

The implementation process of the above operation is described below with a specific example.

Taking the logical qubits q₀, q₁, q₂, and q₃ included in the quantum circuit as an example, before the mapping update, the mapping relationship between the respective logical qubits in the quantum circuit and the respective physical qubits in the chip coupling diagram is the initial mapping relationship πᵢₙᵢₜ: q₀→Q₁, q₁→Q₀, q₂→Q₃, q₃→Q₂.

The initial mapping relationship πᵢₙᵢₜ is shown in the following table:

TABLE 1

| Logical qubits | Physical qubits |
|---|---|
| q₀ | Q₁ |
| q₁ | Q₀ |
| q₂ | Q₃ |
| q₃ | Q₂ |

After the mapping update, the mapping relationship between the respective logical qubits in the quantum circuit and the respective physical qubits in the chip coupling diagram is the target mapping relationship π_{f}: q₀→Q₃, q₁→Q₀, q₂→Q₂, q₃→Q₁.

The target mapping relationship π_{f} is shown in the following table:

TABLE 2

| Logical qubits | Physical qubits |
|---|---|
| q₀ | Q₃ |
| q₁ | Q₀ |
| q₂ | Q₂ |
| q₃ | Q₁ |

According to the above method, firstly, according to operation S310, the first measurement order is acquired, such as an order entered by the user: q₁, q₂, q₃, q₀.

Secondly, according to operation S320, based on the target mapping relationship shown in Table 2, the physical qubit order Q₀, Q₂, Q₁, Q₃ corresponding to the first measurement order q₁, q₂, q₃, q₀ can be obtained.

Then, according to operation S330, the second measurement order q₁, q₃, q₀, q₂ corresponding to the physical qubit order Q₀, Q₂, Q₁, Q₃ is obtained based on the inverse mapping πᵢₙᵢₜ⁻¹: Q₁→q₀, Q₀→q₁, Q₃→q₂, Q₂→q₃ of the initial mapping relationship shown in Table 1.

Finally, according to operation S340, the measurement of the final state is performed on the logical qubits q₁, q₃, q₀, and q₂ successively, and the obtained measurement results are the measurement results of q₁, q₂, q₃, and q₀ desired by the user.

If the user does not enter the first measurement order, a default order can be used as the first measurement order. For example, q₀, q₁, q₂, q₃ is taken as the first measurement order, and the measurement results are output in the above manner.

It can be seen that the above method realizes the measurement of the final state of the mapped physical circuit, which can not only realize output of the measurement results in an order of the logical qubits of the original logic circuit, but also innovatively realize output of the measurement results in any qubit order. The needs of each of quantum programs for the specific qubit measurement are met, and the availability of the fixed qubit circuit is greatly increased.

The embodiment of the present disclosure also provides some exemplary methods to obtain the target mapping relationship, so as to reduce the search space when updating the mapping, and shorten the time of the circuit conversion.

Exemplarily, the above method also includes the manner for obtaining the target mapping relationship, and the manner for obtaining the target mapping relationship includes:

determining the initial mapping relationship between the respective logical qubits and the respective physical qubits;

determining a non-executable target quantum gate in the quantum circuit based on the initial mapping relationship and the chip coupling diagram;

inserting a swap gate into the quantum circuit based on the non-executable target quantum gate; and

updating the initial mapping relationship based on the swap gate, to obtain the target mapping relationships.

Exemplarily, an initial mapping relationship can be determined randomly, or the greedy algorithm, the fastest subgraph isomorphism method, simulated annealing method, etc., in the above description can be used to determine the initial mapping relationship.

Exemplarily, the target quantum gate can include a quantum gate that needs to act on a specific physical qubit in the chip coupling diagram. For example, a quantum gate that needs to act on two adjacent physical qubits, such as a Control-NOT (CNOT) gate. In the embodiment of the present disclosure, a pair of qubits acted on by the target quantum gate can be called as a qubit pair. For example, the above two physical qubits can be called as a physical qubit pair.

In the quantum circuit, if the target quantum gate does not act on a specific physical qubit, the target quantum gate is not executable. For example, when the CNOT gate acts on the logical qubits g₀ and q₁, but the physical qubits corresponding to q₀ and q₁ are not adjacent in the chip coupling diagram, the CNOT gate is not executable.

Exemplarily, the chip coupling diagram can be represented by an undirected graph. Because the chip coupling diagram contains the connectivity relationship of the respective physical qubits, the non-executable target quantum gate in the quantum circuit can be determined based on the initial mapping relationship and the chip coupling diagram.

For example, the swap gate can be used to exchange two qubits. Generally, Swap is realized directly by physics, or by CNOT splicing, or by iSWAP and so on. By inserting a swap gate into the quantum circuit and updating the mapping relationship between the logical qubits and the physical qubits accordingly, the two physical qubits corresponding to the logical qubit pair acted on by the target quantum gate can be close to each other, and the equivalence of the converted quantum circuit can be ensured, which is conducive to obtain, by the conversion, the quantum circuit that can be realized on the physical device.

Exemplarily, the above operation of determining a non-executable target quantum gate in the quantum circuit based on the initial mapping relationship and the chip coupling diagram can include:

determining M logical qubit pairs based on M target quantum gates in the quantum circuit, wherein M is a positive integer;

determining M physical qubit pairs, respectively corresponding to the M logical qubit pairs, in the chip coupling diagram based on the initial mapping relationship;

determining a non-adjacent physical qubit pair in the M physical qubit pairs, based on connectivity relationships between respective physical qubits in the chip coupling diagram; and

determining the non-executable target quantum gate in the M target quantum gates, based on the non-adjacent physical qubit pair.

For example, M=2, the quantum circuit includes a first CNOT gate and a second CNOT gate. The first CNOT gate acts on the logical qubit pair (q₀, q₁), and the second CNOT gate acts on the logical qubit pair(q₀, q₂). Based on the initial mapping relationship, the physical qubits corresponding to q₀, q₁, and q₂ are Q₀, Q₁, and Q₂ respectively, so the first physical qubit pair is (Q₀, Q₁) and the second physical qubit pair is (Q₀, Q₂) in the M physical qubit pairs. If Q₀, Q₁, and Q₂ in the chip coupling diagram are connected in series, a non-adjacent physical qubit pair (Q₀, Q₂) can be determined based on the chip coupling diagram, the corresponding logical qubit pair is (q₀, q₂), and the second CNOT gate acting on (q₀, q₂) is a non-executable quantum gate.

According to the above method, the non-executable target quantum gate in the quantum circuit can be traversed, so that the circuit can be processed and the mapping is updated based on the non-executable target quantum gate, which is conducive to the realization of the quantum circuit on the physical device.

In a practical application, a directed acyclic graph (DAG) can be used to represent the execution constraints between target quantum gates in the quantum circuit. Since the single-qubit gate can always be executed on one qubit, the single-qubit gate is not considered first. The two-qubit gate CNOT (q₁, qⱼ) can only be executed after all previous gates (predecessor gates) on q₁ or qⱼ are executed. Therefore, traversing the whole quantum circuit can construct a DAG to represent the execution dependency relationship of the target quantum gate with a complexity O(g). That is, the DAG is a directed graph of multiple target quantum gates g.

The front layer (denoted as F) is defined as a set of quantum gates, which each have not unexecuted predecessor gates, in the quantum circuit. For a target quantum gate, i.e. a two-qubit gate CNOT (q₁, qⱼ), after all previous gates (predecessor gates) on q₁ or qⱼ are executed, it can be placed in the front layer F. By checking the DAG graph of quantum circuit, all vertices with an in degree of 0 in the graph can be selected and added into F, to initialize F.

All non-executable target quantum gates can be determined by updating the front layer. First, it is checked whether there is a target quantum gate, which can be executed directly on the chip, in F. If there is the target quantum gate, which can be executed directly on the chip, in F, the executable target quantum gates in F are executed, these target quantum gates are removed from F, then the successor gates are checked and the successor gates that meet the requirements of F are added into F. If all target quantum gates in F are not executable on the chip, all the non-executable target quantum gates are determined, a swap gate is insert into the circuit based on the non-executable target quantum gates, and the mapping is updated. The detailed operations of determining the non-executable target quantum gates are as follows:

Operation 1: whether F is empty is checked first. If F is empty, it indicates that all gates in the circuit can be executed directly on the chip, and the algorithm ends. Otherwise, an executable list is initialized and the gates, that can be directly executed on the chip, in F are added into the executable list.

Operation 2: the gates in the executable list are deleted from F. The successor gates of these executable gates are checked. The successor gates that meet the condition of F are added. At this time, the operation 1 is returned to until the executable list is empty, all gates in F are executable in the logic circuit, but are not executable on the chip.

Specifically, the basis for adding a gate in F into the executable list is: for the gate g in F, taking the logical qubit pair (qᵢ, qⱼ) acted on by the gate g in the quantum circuit as an example, and using the mapping relationship at this time to find the physical qubit pair (Qₘ, Qₙ)=[π(qᵢ), π(qₕ)]), on the chip, corresponding to (q₁, qⱼ). If Qₘ and Qₙ are connected by an edge in the chip coupling diagram, the target quantum gate g acting on (qᵢ, qⱼ) can be directly executed on the chip, so it can be added into the executable list.

For the successor gate g of the executable gate, taking g acting on (qᵢ, qⱼ) as an example, the rule for whether it can be added into F is as follows: each of gates in F is checked, and if all gates do not act on qᵢ or qⱼ, g can be added into F.

Exemplarily, after determining the non-executable target quantum gates, the inserting the swap gate into the quantum circuit based on the non-executable target quantum gate, includes:

determining a first physical qubit, corresponding to a first logical qubit acted on by the non-executable target quantum gate, in the chip coupling diagram based on the initial mapping relationship;

determining K second physical qubits adjacent to the first physical qubit in the chip coupling diagram, wherein K is a positive integer;

determining K second logical qubits corresponding to the K second physical qubits based on the inverse mapping relationship of the initial mapping relationship;

obtaining K swap gates based on the K second logical qubits; and

inserting a swap gate with a least cost in the K swap gates into the quantum circuit.

Exemplarily, the first logical qubit is one logical qubit in the logical qubit pair acted on by the target quantum gate. The non-executable target quantum gate acting on (qᵢ, qⱼ) is taken as an example, wherein qᵢ is the first logical qubit. It is assumed that, based on the initial mapping relationship, there is a physical qubit Qⱼ=π(qᵢ), corresponding to qᵢ, in the chip coupling diagram G, so all physical qubits Qⱼ₁, Qⱼ₂, . . . , Qⱼₖ adjacent to Qⱼ are selected in the chip coupling diagram.

The inverse mapping is used to find the corresponding logical qubits: qᵢ₁, qᵢ₂, . . . , qᵢₖ=π⁻¹(Qⱼ₁), π⁻¹(Qⱼ₂), . . . , π⁻¹(Qⱼₖ). Based on the logical qubits qᵢ₁, qᵢ₂, . . . , qᵢₖ, the swap gates respectively acting on the logical qubit pairs (qᵢ₁, qᵢ₁), (qᵢ, qᵢ₂), . . . , (qᵢ, qᵢₖ) are obtained. Since the physical qubits corresponding to these swap gates are connected by sides in the chip coupling diagram G, the swap gates (Swap) acting on these qubit pairs are supported. The above swap gates can be added into the Swaps candidate list. Then, a swap gate to be inserted into the quantum circuit is determined in the Swaps candidate list.

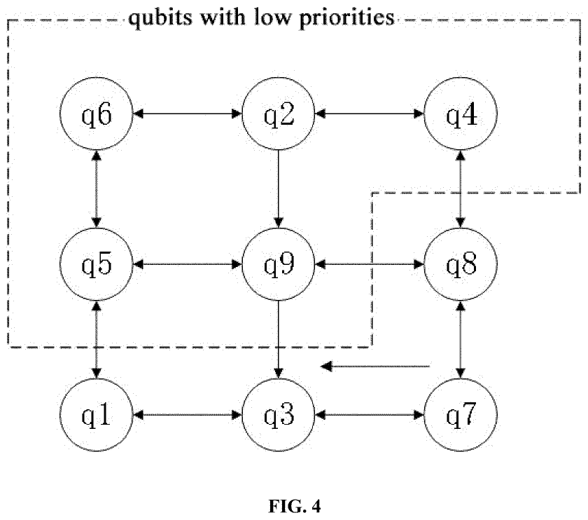

It should be noted that the cost of each swap gate in the above K swap gates can be determined based on the priorities of the logical qubits acted on by the swap gate, the number of subsequent inserted swap gates caused by the swap gate, the resources consumed by inserting the swap gate, and other information. The CNOT(q₁, q₇) and CNOT(q₃, q₈) included in the front layer F is taken as an example, and the physical qubit pairs corresponding thereto are not connected at all in the chip coupling diagram shown in FIG. 4. After q₃ and q₇ are swapped, q₁ is adjacent to q₇, q₃ is adjacent to q₈, the number of times of inserting the swap gates is the lowest, the resource consumption is the lowest, and the qubits acted on by the CNOT gate after swapping are not qubits with low priorities. Therefore, a swap gate acting on (q₃, q₇) is selected in the Swaps candidate list, to be inserted into the quantum circuit.

It can be seen that based on the above method, the comprehensive effect of the swap gate inserted into the quantum circuit can be evaluated, the optimal transformation can be selected, and the circuit that meets the physical constraints can be output.

In a practical application, the F-layer can be iterated based on a heuristic search, a violent search, a random search, a gradient search, or other manners, to complete the conversion of the quantum circuit. Specifically, the heuristic search will iterate until the F layer is empty, which means that all the gates in the circuit have been executed and the algorithm stops. In each iteration, it will first check whether there is a gate, which can be executed directly on the chip, in F. If there is the gate, which can be executed directly on the chip, in F, it will execute these gates and remove these gates from F, then check the successor gates and add the successor gate that meets the requirements of F into F. If all gates in F are not executable on the chip, Swap needs to be inserted into the circuit and the mapping needs to be updated. The detailed algorithm operations are as follows:

Operation 1: whether F is empty is checked first. If F is empty, it indicates that all gates in the circuit can be executed directly on the chip, and the algorithm ends. Otherwise, an executable list is initialized and the gates, which can be directly executed on the chip, in F are added into the executable list.

Operation 2: the gates in the executable list are deleted from F. The successor gates of these executable gates are checked. The successor gates that meet the condition of F are added. At this time, the operation 1 is returned to until the executable list is empty, all gates in F are executable in the logic circuit, but are not executable on the chip, and the next operation is skipped to.

Operation 3: for the gate gin F, the swap gate is inserted into the physical circuit, to move the logical qubits acted on by g closer to each other. According to the method of inserting the Swap, the Swap available for selection is put into the Swaps candidate list.

Operation 4: for the Swap in the Swaps candidate list, the heuristic cost is calculated, and the Swap with the lowest cost is selected to update the mapping π.

Operation 5: after updating the mapping, the operation 1 is skipped to until F is empty, the algorithm ends, the converted quantum circuit and the final mapping are output, that is, the target mapping relationship.

Based on the above methods, fewer extra swap gates need to be inserted in the process of the quantum circuit conversion and the mapping update.

The embodiment of the present disclosure also provides an exemplary and optional manner to determine the initial mapping relationship. Exemplarily, determining the initial mapping relationship between the respective logical qubits and the respective physical qubits, includes:

obtaining a simplified quantum circuit and a reverse circuit of the simplified quantum circuit, based on the target quantum gate in the quantum circuit;

performing N iteration processes based on the simplified quantum circuit and the reverse circuit, to obtain N mapping relationships, wherein N is an integer greater than or equal to 2; and

determining the initial mapping relationship in the N mapping relationships.

Exemplarily, the target quantum gate is a two-bit quantum gate. The single-qubit gate can be removed in the quantum circuit and the two-bit quantum gate is retained only to obtain a simplified quantum circuit. The efficiency can be improved by determining the initial mapping relationship based on the simplified quantum circuit.

Since the initial mapping relationship will have a decisive impact on the overhead of the quantum circuit, the initial mapping relationship given by global consideration will often get an ideal effect. Different from classical circuits and programs, the quantum circuit is reversible. If a mapping relationship can have a good effect on a certain quantum circuit and a reverse circuit thereof, it can be considered that the mapping relationship is preferred. Based on this, in the above implementation, the iteration is performed based on the simplified quantum circuit and the reverse circuit thereof, to obtain multiple mapping relationships and select the optimal one therefrom, which can make the initial mapping relationship globally optimal and reduce the computational overhead of circuit conversion and mapping update.

Exemplarily, an i-th iteration process in the N iteration processes includes:

in a case where i is a first type of numerical value, updating an (i−1)-th mapping relationship in the N mapping relationships based on the simplified quantum circuit and a preset search algorithm, to obtain an i-th mapping relationship in the N mapping relationships;

and/or

in a case where i is a second type of numerical value, updating the (i−1)-th mapping relationship based on the reverse circuit and the search algorithm, to obtain the i-th mapping relationship.

Exemplarily, the first type of numerical value can be an odd number and the second type of numerical value can be an even number; or, the first type of numerical value can be an even number and the second type of numerical value can be an odd number.

According to the above method, the mapping relationship is iteratively updated. Each iteration update is based on the mapping relationship determined in the previous iteration, and the reverse iteration is performed relative to the previous iteration. In this way, the mapping relationship with good forward and reverse effects can be obtained.

Exemplarily, the above preset search algorithm can be the aforementioned heuristic search, A * search, and other algorithms.

Exemplarily, before performing the iteration, the 0-th mapping relationship can be randomly generated or generated by default, to facilitate performing the first iteration.

Exemplarily, determining the initial mapping relationship in the N mapping relationships, includes:

determining a mapping relationship with a least cost in the N mapping relationships as the initial mapping relationship.

By selecting the mapping with the least cost as the initial mapping relationship, the computational overhead of the circuit conversion and mapping update can be reduced effectively.

A specific application example is as follows:

Operation 1: a single-qubit gate is removed in the circuit and a circuit with a two-qubit gate is retained only, which is denoted as a simplified quantum circuit LC. The reverse circuit of LC is determined and is denoted as RE_LC, and DAG diagrams of LC and RE_LC are drawn.

Operation 2: an initial mapping is randomly generated, the heuristic search algorithm based on Swap is called to traverse the LC, to obtain a final mapping.

Operation 3: the final mapping obtained in the operation 2 is taken as the initial mapping of the RE_LC, and the heuristic search based on Swap is called to traverse the reverse circuit RE_LC, to obtain a final mapping.

Operation 4: the final mapping obtained in the operation 3 is taken as the initial mapping of the LC, K (K=10) iterations are performed, and the final initial mapping relationship is determined from multiple final mappings. Herein, the iteration process of acquiring the mapping relationship is performed twice in the operations 1 to 4, thus K=2N, wherein N is the number of times of the above iteration process.

The finally obtained initial mapping has a better quality because the two-qubit quantum gate in the circuit is considered globally. It should be noted that the number of iterations in the operation 4 is preset to 10, which is sufficient for a small-scale circuit. However, in a case where the circuit is large, the number of iterations should be adjusted accordingly to obtain the high-quality initial mapping.

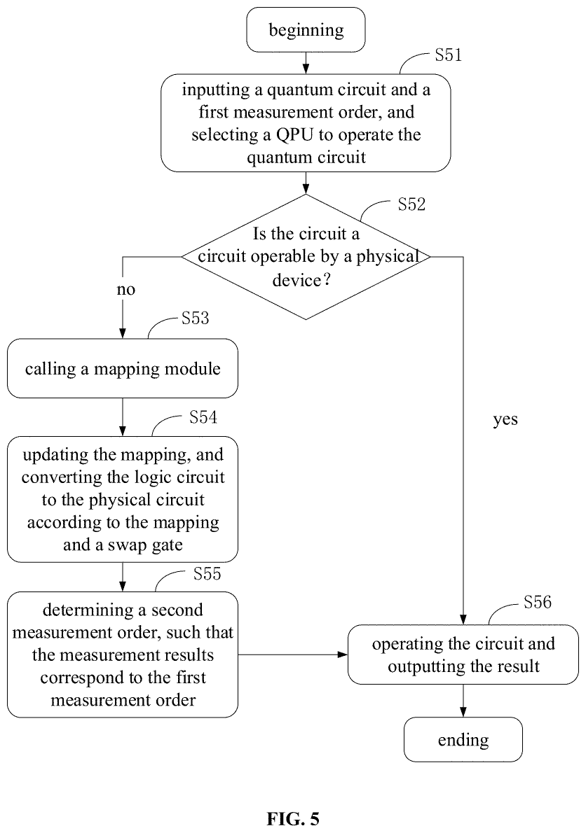

FIG. 5 shows a schematic diagram of a complete example of an embodiment of the present disclosure. As shown in FIG. 5, the method includes:

S51, inputting a quantum circuit and a first measurement order, and selecting a Quantum Processing Unit (QPU) to operate the quantum circuit.

S52, determining whether the input circuit is a circuit operable by a physical device; if the input circuit is the circuit operable by the physical device, skipping to S46. Otherwise, proceeding to the next operation.

S53, calling a mapping module.

S54, updating the mapping, and converting the quantum circuit from a logic circuit to a physical circuit according to the mapping and a swap gate, to obtain a target mapping relationship.

S55, determining a second measurement order based on an initial mapping relationship, the target mapping relationship, and the first measurement order, such that the measurement results correspond to the first measurement order.

S56, operating the circuit and outputting the operation result.

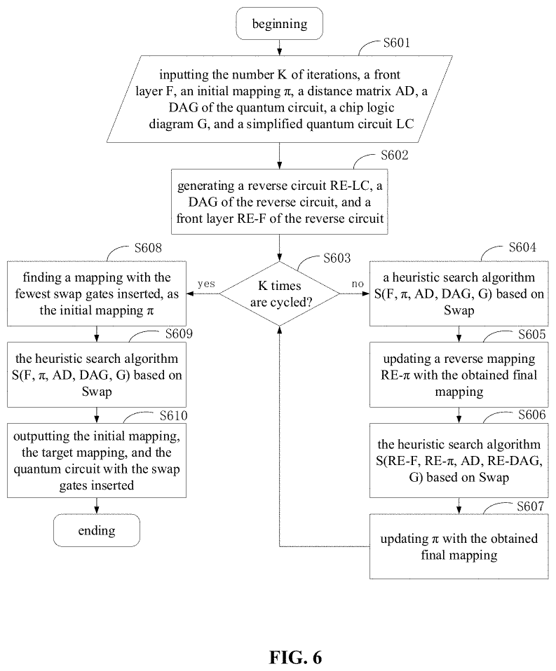

Herein, the specific process of the S54 performed after calling the mapping module can be referred to FIG. 6, including:

S601, inputting the number K of iterations, a front layer F, an initial mapping it, a distance matrix AD, a DAG of the quantum circuit, a chip logic diagram G, and a simplified quantum circuit LC.

S602, generating a reverse circuit RE-LC and a DAG of the reverse circuit, and acquiring a front layer RE-F of the reverse circuit.

S603, determining whether to cycle K times. If K times are cycled, skipping to S608, and otherwise performing S604.

S604, based on the front layer F, the initial mapping it, the distance matrix AD, the DAG of the quantum circuit, and the chip logic diagram G, performing a heuristic search algorithm S(F, π, AD, DAG, G) based on Swap, to obtain a final mapping.

S605, updating a reverse mapping RE-π with the obtained final mapping.

S606, based on the front layer F of the reverse circuit, the reverse mapping RE-π, the distance matrix AD, a DAG of the reverse circuit, and the chip logic diagram G, performing the heuristic search algorithm S(RE-F, RE-π, AD, RE-DAG, G) based on Swap, to obtain the final mapping.

S607, updating it with the obtained final mapping and returning to S603.

S608, finding, from 2K mappings obtained by K cycles, a mapping with the fewest swap gates inserted, as the initial mapping it.

S609, performing the heuristic search algorithm S(F, π, AD, DAG, G) based on Swap, based on the front layer F, the initial mapping it, the distance matrix AD, the DAG of the quantum circuit, and the chip logic diagram G.

S610, outputting the initial mapping, the target mapping, and the quantum circuit with the swap gates inserted. The mapping process ends.

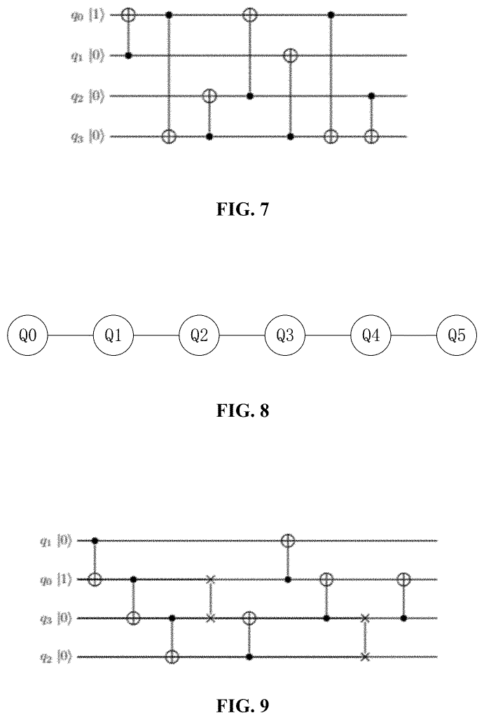

The mapping update and circuit conversion process of the above quantum circuit are described below with specific application examples. FIG. 7 shows a quantum circuit before conversion in this example. The quantum circuit is a logic circuit that cannot be performed on a physical device.

For the convenience of expression, 7 CNOT gates from left to right in FIG. 7 are denoted as g₁, g₂, . . . , g₇ respectively.

It is assumed that the chip coupling layout is linear, and the chip coupling diagram is shown in FIG. 8. Based on the circuit and the reverse circuit of FIG. 7, the reverse traversal determines the initial mapping as πᵢₙᵢₜ: q₀→Qᵢ₀, q₁→Qᵢ₁, q₂→Qᵢ₂, q₃→Qᵢ₃, wherein the subscripts i0, i1, i2, and i3 are a certain arrangement of {0, 1, 2, 3}. In this example, the initial mapping is πᵢₙᵢₜ: q₀→Q₁, q₁→Q₀, q₂→Q₃, q₃→Q₂.

The presentation of each of gates in the logic circuit in FIG. 7 in the physical circuit is analyzed below:

g₁ acts on q₁ and q₀, corresponding to Q₀ and Q₁, under the initial mapping. In the chip coupling diagram, Q₀ is adjacent to Q₁, and both can be acted on by the two-bit gate (the target quantum gate).

The situations of g₂ and g₃ are the same as the situation of g₁.

G₄ acts on q₂ and q₀, corresponding to Q₃ and Q₁, under the initial mapping. In the chip coupling diagram, Q₃ is not adjacent to Q₁, and both cannot be acted on by the two-qubit gate. Therefore, it is necessary to insert the swap gate. According to the search algorithm, the swap gate acts on on q₀ and q₃, and the mapping relationship is updated accordingly and is denoted as π₁: q₀→Q₂, q₁→Q₀, q₂→Q₃, q₃→Q₁. At this time, g₄ acts on q₂ and q₀, corresponding to physical qubits Q₃ and Q₂, which are adjacent to each other in the chip coupling diagram G, and can be acted on by the two-qubit gate.

Under the mapping π₁, g₄, g₅, and g₆ all meet the physical constraints, so they can act directly.

g₇ acts on q₂ and q₃, corresponding to Q₃ and Q₁, under the mapping π₁. In the chip coupling diagram, Q₃ is not adjacent to Q₁, and both cannot be acted on by the two-qubit gate. Therefore, it is necessary to insert the swap gate. According to the search algorithm, the swap gate acts on q₀ and q₂, and the mapping relationship is updated accordingly and is denoted as π₂: q₀→Q₃, q₁→Q₀, q₂→Q₂, q₃→Q₁. At this time, g₇ acts on q₂ and q₃, corresponding to physical qubits Q₂ and Q₁, which are adjacent to each other in the chip coupling diagram G, and can be acted on by the two-qubit gate.

Based on the above conversion, a converted quantum circuit as shown in FIG. 9 is obtained, and the circuit can be a physical circuit performed on the physical device. The measurement of the physical circuit can be realized with reference to the above embodiments.

It can be seen that according to the method of the present disclosure, since the initial mapping relationship and the target mapping relationship, obtained by updating, clearly describe the mapping relationships between the logical qubits in the quantum circuit and the physical qubits in the chip coupling diagram before and after the mapping update, the final state measurement of the quantum circuit after the qubit mapping is realized based on the initial mapping relationship and the target mapping relationship. Moreover, the measurement results can be output based on the obtained first measurement order, which can meet the needs of different quantum programs for the specific qubit measurement and increase the availability of the quantum circuit.

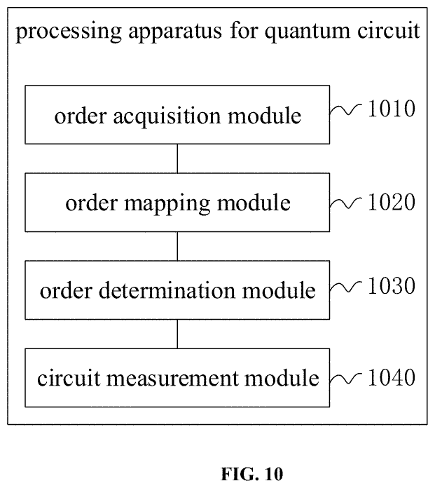

As an implementation of the above method, an embodiment of the present disclosure further provides a processing apparatus for a quantum circuit. As shown in FIG. 10, the apparatus includes:

an order acquisition module 1010, configured for acquiring a first measurement order of respective logical qubits in the quantum circuit;

an order mapping module 1020, configured for determining a physical qubit order corresponding to the first measurement order based on a target mapping relationship between the respective logical qubits and respective physical qubits in a chip coupling diagram, wherein the target mapping relationship is obtained by updating based on an initial mapping relationship between the respective logical qubits and the respective physical qubits;

an order determination module 1030, configured for determining a second measurement order of the respective logical qubits of the quantum circuit based on the physical qubit order and the initial mapping relationship; and

a circuit measurement module 1040, configured for measuring the quantum circuit based on the second measurement order, to obtain a measurement result.

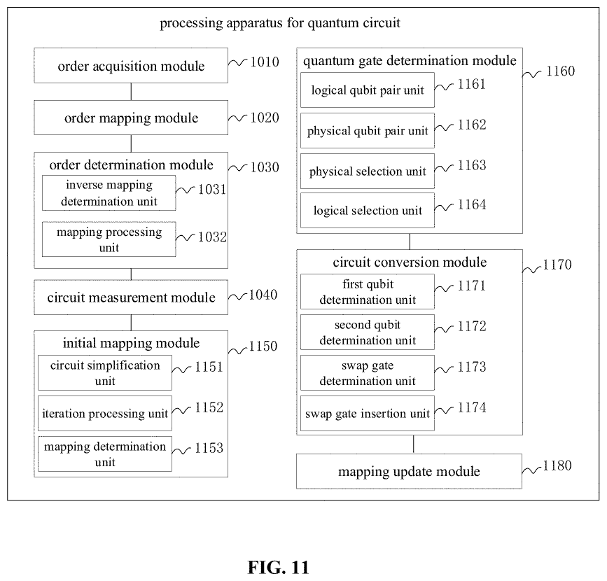

Exemplarily, as shown in FIG. 11, the order determination module 1030 includes:

an inverse mapping determination unit 1031, configured for determining an inverse mapping relationship of the initial mapping relationship, wherein the inverse mapping relationship is a mapping relationship between the respective physical qubits and the respective logical qubits; and

a mapping processing unit 1032, configured for mapping the physical qubit order based on the inverse mapping relationship, to obtain the second measurement order of the respective logical qubits.

Exemplarily, as shown in FIG. 11, the processing apparatus for the quantum circuit further includes:

an initial mapping module 1150, configured for determining the initial mapping relationship between the respective logical qubits and the respective physical qubits;

a quantum gate determination module 1160, configured for determining a non-executable target quantum gate in the quantum circuit based on the initial mapping relationship and the chip coupling diagram;

a circuit conversion module 1170, configured for inserting a swap gate into the quantum circuit based on the non-executable target quantum gate; and

a mapping update module 1180, configured for updating the initial mapping relationship based on the swap gate, to obtain the target mapping relationships.

As shown in FIG. 11, the initial mapping module 1150 includes:

a circuit simplification unit 1151, configured for obtaining a simplified quantum circuit and a reverse circuit of the simplified quantum circuit, based on the target quantum gate in the quantum circuit;

an iteration processing unit 1152, configured for performing N iteration processes based on the simplified quantum circuit and the reverse circuit, to obtain N mapping relationships, wherein N is an integer greater than or equal to 2; and

a mapping determination unit 1153, configured for determining the initial mapping relationship in the N mapping relationships.

An i-th iteration process in the N iteration processes includes:

in a case where i is a first type of numerical value, updating an (i−1)-th mapping relationship in the N mapping relationships based on the simplified quantum circuit and a preset search algorithm, to obtain an i-th mapping relationship in the N mapping relationships;

and/or

in a case where i is a second type of numerical value, updating the (i−1)-th mapping relationship based on the reverse circuit and the search algorithm, to obtain the i-th mapping relationship.

Exemplarily, the mapping determination unit 1153 is specifically configured for:

determining a mapping relationship with a least cost in the N mapping relationships as the initial mapping relationship.

As shown in FIG. 11, the quantum gate determination module 1160 includes:

a logical qubit pair unit 1161, configured for determining M logical qubit pairs based on M target quantum gates in the quantum circuit, wherein M is a positive integer;

a physical qubit pair unit 1162, configured for determining M physical qubit pairs, respectively corresponding to the M logical qubit pairs, in the chip coupling diagram based on the initial mapping relationship;

a physical selection unit 1163, configured for determining a non-adjacent physical qubit pair in the M physical qubit pairs, based on connectivity relationships between the respective physical qubits in the chip coupling diagram; and

a logical selection unit 1164, configured for determining the non-executable target quantum gate in the M target quantum gates, based on the non-adjacent physical qubit pair.

As shown in FIG. 11, the circuit conversion module 1170 includes:

a first qubit determination unit 1171, configured for determining a first physical qubit, corresponding to a first logical qubit acted on by the non-executable target quantum gate, in the chip coupling diagram based on the initial mapping relationship;

a second qubit determination unit 1172, configured for determining K second physical qubits adjacent to the first physical qubit in the chip coupling diagram, and determining K second logical qubits corresponding to the K second physical qubits based on the inverse mapping relationship of the initial mapping relationship, wherein K is a positive integer;

a swap gate determination unit 1173, configured for obtaining K swap gates based on the K second logical qubits; and

a swap gate insertion unit 1174, configured for inserting a swap gate with a least cost in the K swap gates into the quantum circuit.

The function of each unit, module, or submodule in each apparatus of the embodiments of the present disclosure can be referred to the corresponding description in the above method embodiment, which will not be repeated here.

According to an embodiment of the present disclosure, the present disclosure also provides an electronic device, a readable storage medium, and a computer program product.

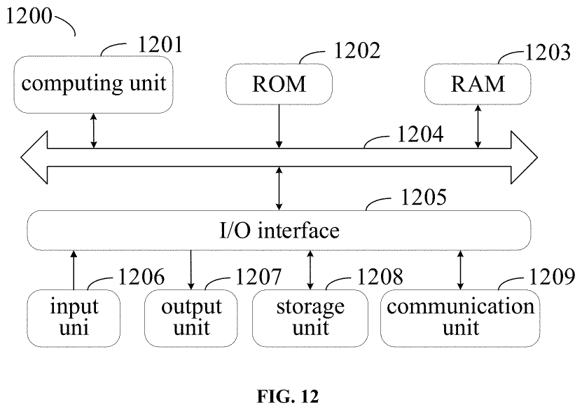

FIG. 12 shows a schematic block diagram of an example electronic device 1200 that may be used to implement embodiments of the present disclosure. The electronic device is intended to represent various forms of digital computers, such as laptop computers, desktop computers, workbenches, personal digital assistants, servers, blade servers, mainframe computers, and other suitable computers. The electronic device may also represent various forms of mobile apparatuses, such as personal digital assistants, cellular phones, smart phones, wearable devices, and other similar computing apparatuses. The components shown herein, their connections and relationships, and their functions are merely examples, and are not intended to limit the implementation of the present disclosure described and/or claimed herein.

As shown in FIG. 12, the electronic device 1200 includes a computing unit 1201 that can perform various appropriate actions and processes according to a computer program stored in a read only memory (ROM) 1202 or a computer program loaded from the storage unit 1208 into a random access memory (RAM) 1203. In the RAM 1203, various programs and data required for the operation of the electronic device 1200 can also be stored. The computing unit 1201, the ROM 1202, and the RAM 1203 are connected to each other through a bus 1204. The input/output (I/O) interface 1205 is also connected to the bus 1204.

A plurality of components in the electronic device 1200 are connected to the I/O interface 1205, including: an input unit 1206, such as a keyboard, a mouse, etc; an output unit 1207, such as various types of displays, speakers, etc; a storage unit 1208, such as a magnetic disk, an optical disk, etc; and a communication unit 1209, such as a network card, a modem, a wireless communication transceiver, etc. The communication unit 1209 allows the electronic device 1200 to exchange information/data with other devices through computer networks such as the Internet and/or various telecommunication networks.

The computing unit 1201 may be various general-purpose and/or special-purpose processing components with processing and computing capabilities. Some examples of the computing unit 1201 include, but are not limited to, a central processing unit (CPU), a graphics processing unit (GPU), various special-purpose artificial intelligence (AI) computing chips, various computing units running machine learning model algorithms, digital signal processors (DSPs), and any appropriate processors, controllers, microcontrollers, etc. The computing unit 1201 performs various methods and processes described above, such as a processing method for a quantum circuit. For example, in some embodiments, the processing method for a quantum circuit may be implemented as a computer software program that is tangibly contained in a machine-readable medium, such as a storage unit 1208. In some embodiments, part or all of the computer program may be loaded and/or installed on the electronic device 1200 via the ROM 1202 and/or the communication unit 1209. When the computer program is loaded into the RAM 1203 and performed by the computing unit 1201, one or more operations of the processing method for a quantum circuit described above may be performed. Optionally, in other embodiments, the computing unit 1201 may be configured for performing the processing method for the quantum circuit by any other suitable means (for example, by means of firmware).

Various embodiments of the systems and technologies described above herein can be implemented in a digital electronic circuit system, an integrated circuit system, a field programmable gate array (FPGA), an application specific integrated circuit (ASIC), an application special standard product (ASSP), a system on chip (SOC), a load programmable logic device (CPLD), a computer hardware, firmware, software and/or combinations thereof. These various embodiments may include: implementations in one or more computer programs which may be executed and/or interpreted on a programmable system that includes at least one programmable processor, which may be a special-purpose or general-purpose programmable processor that may receive data and instructions from a storage system, at least one input device, and at least one output device, and transmit the data and instructions to the storage system, the at least one input device, and the at least one output device.

The program codes for implementing the method of the present disclosure may be written in any combination of one or more programming languages. These program codes can be provided to the processor or controller of a general-purpose computer, a special-purpose computer or other programmable data processing apparatuses, such that the program codes, when executed by the processor or controller, enables the functions/operations specified in the flowchart and/or block diagram to be implemented. The program codes can be executed completely on the machine, partially on the machine, partially on the machine and partially on the remote machine as a separate software package, or completely on the remote machine or server.

In the context of the present disclosure, a machine-readable medium may be a tangible medium that may contain or store programs for use by or in combination with an instruction execution system, apparatus, or device. The machine-readable medium may be a machine-readable signal medium or a machine-readable storage medium. The machine readable medium may include, but is not limited to, an electronic, magnetic, optical, electromagnetic, infrared, or semiconductor system, apparatus, or device, or any suitable combination of the above contents. A more specific example of the machine-readable storage medium will include an electrical connection based on one or more lines, a portable computer disk, a hard disks, a random access memory (RAM), a read only memory (ROM), an erasable programmable read only memory (EPROM or flash memory), an optical fiber, a portable compact disk read only memory (CD-ROM), an optical storage device, a magnetic storage device, or any suitable combination of the above contents.

In order to provide interactions with a user, the system and technology described herein may be implemented on a computer which has: a display apparatus (for example, a CRT (cathode ray tube) or an LCD (liquid crystal display) monitor) for displaying information to the user; and a keyboard and pointing apparatus (for example, a mouse or a trackball), through which the user may provide input to the computer. Other kinds of devices may also be used to provide interactions with a user; for example, the feedback provided to a user may be any form of sensory feedback (for example, visual feedback, auditory feedback, or tactile feedback); and input from a user may be received using any form (including acoustic input, voice input, or tactile input).

The systems and techniques described herein may be implemented in a computing system (for example, as a data server) that includes back-end components, or be implemented in a computing system (for example, an application server) that includes middleware components, or be implemented in a computing system (for example, a user computer with a graphical user interface or a web browser through which the user may interact with the implementation of the systems and technologies described herein) that includes front-end components, or be implemented in a computing system that includes any combination of such back-end components, intermediate components, or front-end components. The components of the system may be interconnected by any form or medium of digital data communication (for example, a communication network). The example of the communication network includes a local area network (LAN), a wide area network (WAN), and the Internet.

The computer system may include a client and a server. The client and the server are generally remote from each other and typically interact through a communication network. The client-server relationship is generated by computer programs that run on respective computers and have a client-server relationship with each other. The server can be a cloud server, a server of a distributed system, or a server combined with a blockchain.

It should be understood that various forms of processes shown above may be used to reorder, add, or delete operations. For example, respective operations described in the present disclosure may be executed in parallel, or may be executed sequentially, or may be executed in a different order, as long as the desired result of the technical solution disclosed in the present disclosure can be achieved, no limitation is made herein.

The above specific embodiments do not constitute a limitation on the protection scope of the present disclosure. It should be understood by those skilled in the art that various modifications, combinations, sub-combinations, and substitutions may be made according to design requirements and other factors. Any modification, equivalent replacement and improvement, and the like made within the spirit and principle of the present disclosure shall be fall in the protection scope of the present disclosure.

What is claimed is:

1. A processing method for a quantum circuit, comprising:
acquiring a first measurement order of respective logical qubits in the quantum circuit;
determining a physical qubit order corresponding to the first measurement order based on a target mapping relationship between the respective logical qubits and respective physical qubits in a chip coupling diagram, wherein the target mapping relationship is obtained by updating based on an initial mapping relationship between the respective logical qubits and the respective physical qubits;
determining a second measurement order of the respective logical qubits of the quantum circuit based on the physical qubit order and the initial mapping relationship; and
measuring the quantum circuit based on the second measurement order, to obtain a measurement result.

2. The method of claim 1, wherein the determining the second measurement order of the respective logical qubits of the quantum circuit based on the physical qubit order and the initial mapping relationship, comprises:
determining an inverse mapping relationship of the initial mapping relationship, wherein the inverse mapping relationship is a mapping relationship between the respective physical qubits and the respective logical qubits; and
mapping the physical qubit order based on the inverse mapping relationship, to obtain the second measurement order of the respective logical qubits.

3. The method of claim 1, further comprising:
determining the initial mapping relationship between the respective logical qubits and the respective physical qubits;
determining a non-executable target quantum gate in the quantum circuit based on the initial mapping relationship and the chip coupling diagram;
inserting a swap gate into the quantum circuit based on the non-executable target quantum gate; and
updating the initial mapping relationship based on the swap gate, to obtain the target mapping relationship.

4. The method of claim 3, wherein the determining the initial mapping relationship between the respective logical qubits and the respective physical qubits, comprises:
obtaining a simplified quantum circuit and a reverse circuit of the simplified quantum circuit, based on the target quantum gate in the quantum circuit;
performing N iteration processes based on the simplified quantum circuit and the reverse circuit, to obtain N mapping relationships, wherein N is an integer greater than or equal to 2; and
determining the initial mapping relationship in the N mapping relationships.

5. The method of claim 4, wherein an i-th iteration process in the N iteration processes comprises:
in a case where i is a first type of numerical value, updating an (i−1)-th mapping relationship in the N mapping relationships based on the simplified quantum circuit and a preset search algorithm, to obtain an i-th mapping relationship in the N mapping relationships;
and/or
in a case where i is a second type of numerical value, updating the (i−1)-th mapping relationship based on the reverse circuit and the search algorithm, to obtain the i-th mapping relationship.

6. The method of claim 4, wherein the determining the initial mapping relationship in the N mapping relationships, comprises:
determining a mapping relationship with a least cost in the N mapping relationships as the initial mapping relationship.

7. The method of claim 3, wherein the determining the non-executable target quantum gate in the quantum circuit based on the initial mapping relationship and the chip coupling diagram, comprises:
determining M logical qubit pairs based on M target quantum gates in the quantum circuit, wherein M is a positive integer;
determining M physical qubit pairs, respectively corresponding to the M logical qubit pairs, in the chip coupling diagram based on the initial mapping relationship;
determining a non-adjacent physical qubit pair in the M physical qubit pairs, based on connectivity relationships between the respective physical qubits in the chip coupling diagram; and
determining the non-executable target quantum gate in the M target quantum gates, based on the non-adjacent physical qubit pair.

8. The method of claim 3, wherein the inserting the swap gate into the quantum circuit based on the non-executable target quantum gate, comprises:
determining a first physical qubit, corresponding to a first logical qubit acted on by the non-executable target quantum gate, in the chip coupling diagram based on the initial mapping relationship;
determining K second physical qubits adjacent to the first physical qubit in the chip coupling diagram, wherein K is a positive integer;
determining K second logical qubits corresponding to the K second physical qubits based on the inverse mapping relationship of the initial mapping relationship;
obtaining K swap gates based on the K second logical qubits; and
inserting a swap gate with a least cost in the K swap gates into the quantum circuit.

9. An electronic device, comprising:
at least one processor; and
a memory connected communicatively to the at least one processor, wherein the memory stores instructions executable by the at least one processor, and the instructions, when executed by the at least one processor, enable the at least one processor to perform operations of:
acquiring a first measurement order of respective logical qubits in the quantum circuit;
determining a physical qubit order corresponding to the first measurement order based on a target mapping relationship between the respective logical qubits and respective physical qubits in a chip coupling diagram, wherein the target mapping relationship is obtained by updating based on an initial mapping relationship between the respective logical qubits and the respective physical qubits;
determining a second measurement order of the respective logical qubits of the quantum circuit based on the physical qubit order and the initial mapping relationship; and
measuring the quantum circuit based on the second measurement order, to obtain a measurement result.

10. The electronic device of claim 9, wherein the determining the second measurement order of the respective logical qubits of the quantum circuit based on the physical qubit order and the initial mapping relationship, comprises:
determining an inverse mapping relationship of the initial mapping relationship, wherein the inverse mapping relationship is a mapping relationship between the respective physical qubits and the respective logical qubits; and
mapping the physical qubit order based on the inverse mapping relationship, to obtain the second measurement order of the respective logical qubits.

11. The electronic device of claim 9, wherein the instructions, when executed by the at least one processor, enable the at least one processor to further perform operations of:
determining the initial mapping relationship between the respective logical qubits and the respective physical qubits;
determining a non-executable target quantum gate in the quantum circuit based on the initial mapping relationship and the chip coupling diagram;
inserting a swap gate into the quantum circuit based on the non-executable target quantum gate; and
updating the initial mapping relationship based on the swap gate, to obtain the target mapping relationship.

12. The electronic device of claim 11, wherein the determining the initial mapping relationship between the respective logical qubits and the respective physical qubits, comprises:
obtaining a simplified quantum circuit and a reverse circuit of the simplified quantum circuit, based on the target quantum gate in the quantum circuit;
performing N iteration processes based on the simplified quantum circuit and the reverse circuit, to obtain N mapping relationships, wherein N is an integer greater than or equal to 2; and
determining the initial mapping relationship in the N mapping relationships.

13. The electronic device of claim 12, wherein an i-th iteration process in the N iteration processes comprises:
in a case where i is a first type of numerical value, updating an (i−1)-th mapping relationship in the N mapping relationships based on the simplified quantum circuit and a preset search algorithm, to obtain an i-th mapping relationship in the N mapping relationships;
and/or
in a case where i is a second type of numerical value, updating the (i−1)-th mapping relationship based on the reverse circuit and the search algorithm, to obtain the i-th mapping relationship.

14. The electronic device of claim 12, wherein the determining the initial mapping relationship in the N mapping relationships, comprises:
determining a mapping relationship with a least cost in the N mapping relationships as the initial mapping relationship.

15. The electronic device of claim 11, wherein the determining the non-executable target quantum gate in the quantum circuit based on the initial mapping relationship and the chip coupling diagram, comprises:
determining M logical qubit pairs based on M target quantum gates in the quantum circuit, wherein M is a positive integer;
determining M physical qubit pairs, respectively corresponding to the M logical qubit pairs, in the chip coupling diagram based on the initial mapping relationship;
determining a non-adjacent physical qubit pair in the M physical qubit pairs, based on connectivity relationships between the respective physical qubits in the chip coupling diagram; and
determining the non-executable target quantum gate in the M target quantum gates, based on the non-adjacent physical qubit pair.

16. The electronic device of claim 11, wherein the inserting the swap gate into the quantum circuit based on the non-executable target quantum gate, comprises:
determining a first physical qubit, corresponding to a first logical qubit acted on by the non-executable target quantum gate, in the chip coupling diagram based on the initial mapping relationship;
determining K second physical qubits adjacent to the first physical qubit in the chip coupling diagram, wherein K is a positive integer;
determining K second logical qubits corresponding to the K second physical qubits based on the inverse mapping relationship of the initial mapping relationship;
obtaining K swap gates based on the K second logical qubits; and
inserting a swap gate with a least cost in the K swap gates into the quantum circuit.

17. A non-transitory computer-readable storage medium storing computer instructions, wherein the computer instructions, when executed by a computer, cause the computer to perform operations of:
acquiring a first measurement order of respective logical qubits in the quantum circuit;
determining a physical qubit order corresponding to the first measurement order based on a target mapping relationship between the respective logical qubits and respective physical qubits in a chip coupling diagram, wherein the target mapping relationship is obtained by updating based on an initial mapping relationship between the respective logical qubits and the respective physical qubits;
determining a second measurement order of the respective logical qubits of the quantum circuit based on the physical qubit order and the initial mapping relationship; and
measuring the quantum circuit based on the second measurement order, to obtain a measurement result.

18. The non-transitory computer-readable storage medium of claim 17, wherein the determining the second measurement order of the respective logical qubits of the quantum circuit based on the physical qubit order and the initial mapping relationship, comprises:
determining an inverse mapping relationship of the initial mapping relationship, wherein the inverse mapping relationship is a mapping relationship between the respective physical qubits and the respective logical qubits; and
mapping the physical qubit order based on the inverse mapping relationship, to obtain the second measurement order of the respective logical qubits.

19. The non-transitory computer-readable storage medium of claim 17, wherein the computer instructions, when executed by the computer, cause the computer to further perform operations of:
determining the initial mapping relationship between the respective logical qubits and the respective physical qubits;
determining a non-executable target quantum gate in the quantum circuit based on the initial mapping relationship and the chip coupling diagram;
inserting a swap gate into the quantum circuit based on the non-executable target quantum gate; and
updating the initial mapping relationship based on the swap gate, to obtain the target mapping relationship.

20. The non-transitory computer-readable storage medium of claim 19, wherein the determining the initial mapping relationship between the respective logical qubits and the respective physical qubits, comprises:
obtaining a simplified quantum circuit and a reverse circuit of the simplified quantum circuit, based on the target quantum gate in the quantum circuit;
performing N iteration processes based on the simplified quantum circuit and the reverse circuit, to obtain N mapping relationships, wherein N is an integer greater than or equal to 2; and
determining the initial mapping relationship in the N mapping relationships.
